(19) United States
(12) Patent Application Publication
(10) Pub. No.: US 2016/0176192 A1
(43) Pub. Date: Jun. 23, 2016

(54) METHOD FOR MACHINING SILICON SUBSTRATE, AND LIQUID EJECTION HEAD

(71) Applicant: CANON KABUSHIKI KAISHA, Tokyo (JP)

(72) Inventor: Yoshiyuki Fukumoto, Kawasaki-shi (JP)

(21) Appl. No.: 14/964,409

(22) Filed: Dec. 9, 2015

(30) Foreign Application Priority Data
Dec. 19, 2014 (JP) 2014-256865

(51) Int. Cl. B41J 2/16; H01L 21/62; B41J 2/14; H01L 21/027

(52) U.S. Cl. CPC B41J 2/162; H01L 21/027; H01L 21/62; B41J 2/1433; B41J 2/1628

(57) ABSTRACT

A method for machining a silicon substrate through which a through-hole is created in the silicon substrate and a structure of a liquid ejection head using this method, wherein first recesses are machined in a first surface of a silicon substrate, and a sidewall-protecting film is formed on the side walls of the first recesses. The bottom section of the first recesses is then etched. After that, cavities are created that have a larger cross-sectional area than the first recesses in the horizontal direction of the substrate, and an etching stopper film is formed on the inner walls of the cavities. A second recess is then machined from a second surface of the silicon substrate to make at least part of the etching stopper film exposed. Lastly, the etching stopper film is removed to make the first recesses communicate with the second recess, completing a through-hole.

### BACKGROUND OF THE INVENTION

1. Field of the Invention

The present disclosure relates to a method for machining a silicon substrate through which a through-hole is created in the silicon substrate and to a structure of a liquid ejection head using this method.

2. Description of the Related Art

Many MEMS (micro-electro-mechanical systems) devices are produced through the machining of a silicon substrate. An example of a MEMS device is a liquid ejection head, a head configured to eject liquid.

An example of a liquid ejection head is an inkjet recording head, a head configured to eject ink to produce an image. Inkjet recording heads incorporate a silicon substrate having an energy generator, an element configured to generate energy to eject liquid, on its front side. The silicon substrate has an ink supply path machined in the form of a through-hole, and on the silicon substrate there is a nozzle-perforated component covering the ink path. The nozzle-perforated component has a nozzle through which the liquid is ejected.

High-definition image production requires that multiple nozzles be integrated in a dense array. This can be ensured through the reduction of the open area of the ink supply path on the front side of the substrate and dense arrangement of wiring and circuits.

An example of a way to reduce the open area of the ink supply path is such an inkjet recording head as described in Japanese Patent Laid-Open No. 2009-096036. FIG. 1 illustrates its cross-sectional view. The inkjet recording head illustrated in FIG. 1 has a two-level, through-hole-structured ink supply path, which includes a trench-shaped second ink supply path 106 machined from the back surface of a silicon substrate 101, the surface opposite the front side on which energy generators 107 are situated, and first ink supply paths 105 which are multiple small holes machined from the bottom surface of the second ink supply path 106.

An example of a method for machining such a two-level through-hole is to etch a silicon substrate only from its back side, such as a method disclosed in Japanese Patent Laid-Open No. 2009-096036. This method involves processing a silicon substrate using orientation-dependent anisotropic wet etching starting from its back surface to machine a trench as the second ink supply path 106. Then, with an etching mask on the bottom surface of the trench, multiple small holes for use as the first ink supply paths 105 are machined through dry etching.

This method, involving machining the silicon substrate 101 to a considerable depth from its back side, causes the through-hole to experience a change in its cross-sectional shape while being machined, resulting in low shape accuracy of the openings of the first ink supply paths on the front side of the silicon substrate. Low shape accuracy of the openings of the first ink supply paths necessitates allowing a large tolerance, making it difficult to integrating the nozzles in a dense array.

The shape accuracy of openings can be enhanced through a production method that involves machining part of an ink supply path from the front side of the substrate and then from the back side to machine the rest to make the two parts communicate. An example of such a machining method is a production process disclosed in Japanese Patent Laid-Open No. 2004-237734. This process involves dry-etching first ink supply paths 105 first from the front side of a silicon substrate 101 on which energy generators 107 have been formed, and lastly dry-etching a second ink supply path 106 from the back side of the silicon substrate to make it communicate with the first ink supply paths 105, completing an ink supply path through the silicon substrate 101. FIG. 2 illustrates a cross-sectional view of a resulting inkjet recording head. The shape of the openings of the first ink supply path on the front side of the silicon substrate is determined by an etching mask formed on the front surface of the silicon substrate, and this ensures high shape accuracy of the openings.

### SUMMARY OF THE INVENTION

An aspect of the present disclosure provides a method for machining a silicon substrate. In producing a structure including a silicon substrate, multiple first hole sections machined from the front side of the silicon substrate, and a second hole section machined from the back side of the substrate to communicate with the first hole sections, this method enables formation of the first hole sections with good depth accuracy.

Another aspect of the present disclosure provides a method for machining a silicon substrate that additionally enables formation of the second hole section with good depth accuracy.
An aspect of the present disclosure provides a method for machining a silicon substrate by creating a hole section through the silicon substrate from a first surface to the opposite second surface of the substrate. The method includes:

(A) machining a first recess in the first surface of the silicon substrate;

(B) forming a sidewall-protecting film on a side wall of the first recess;

(C) etching a bottom section of the first recess to create a cavity having a larger spatial-cross-sectional-area section than the first recess in a horizontal direction of the substrate;

(D) forming an etching stopper film on at least an inner wall of the cavity extending in the horizontal direction of the substrate;

(E) machining a second recess from the second surface of the silicon substrate;

(F) making the etching stopper film exposed in at least part of the second recess; and

(G) removing at least part of the exposed etching stopper film to make the first recess communicate with the second recess.

Further features of the present disclosure will become apparent from the following description of exemplary embodiments with reference to the attached drawings.

### BRIEF DESCRIPTION OF THE DRAWINGS

FIG. 1 is a cross-sectional view of a liquid ejection head produced using a technology in the related art.

FIG. 2 is a cross-sectional view of a liquid ejection head produced using another technology in the related art.

FIG. 3 illustrates a distribution of depths of a first ink supply path of a liquid ejection head produced using a known technology.

FIGS. 4A to 4K are cross-sectional process diagrams illustrating a method according to one or more Embodiments of the subject disclosure for producing a liquid ejection head.

FIGS. 5A and 5B are cross-sectional diagrams illustrating methods for producing a liquid ejection head as part of describing one or more Embodiments. FIG. 5A illustrates an exemplary alternative according to the same embodiment, and FIG. 5B a comparative alternative which does not fall within the scope of any aspect of the subject disclosure.

FIGS. 6A to 6L are cross-sectional process diagrams illustrating a method according to one or more Embodiments of the subject disclosure for producing a liquid ejection head.

FIGS. 7A to 7I are cross-sectional process diagrams illustrating a method according to one or more Embodiments of the subject disclosure for producing a liquid ejection head.

FIGS. 8A, 8B, and 8C are a plan view, a cross-sectional view along line VIIIB-VIIIB, and a cross-sectional view along line VIIIC-VIIIC, respectively, of a liquid ejection head produced in accordance with one or more Embodiments of the subject disclosure.

FIGS. 9A, 9B, and 9C are a plan view, a cross-sectional view along line IXB-IXB, and a cross-sectional view along line IXC-IXC, respectively, of another example of a liquid ejection head produced in accordance with one or more Embodiments of the subject disclosure.

FIGS. 10A to 10E are cross-sectional process diagrams illustrating another method for producing the second hole section for a liquid ejection head produced in accordance with one or more Embodiments of the subject disclosure.

FIGS. 11A to 11G are cross-sectional process diagrams illustrating a method according to one or more Embodiments of the subject disclosure for producing a liquid ejection head.

### DESCRIPTION OF THE EMBODIMENTS

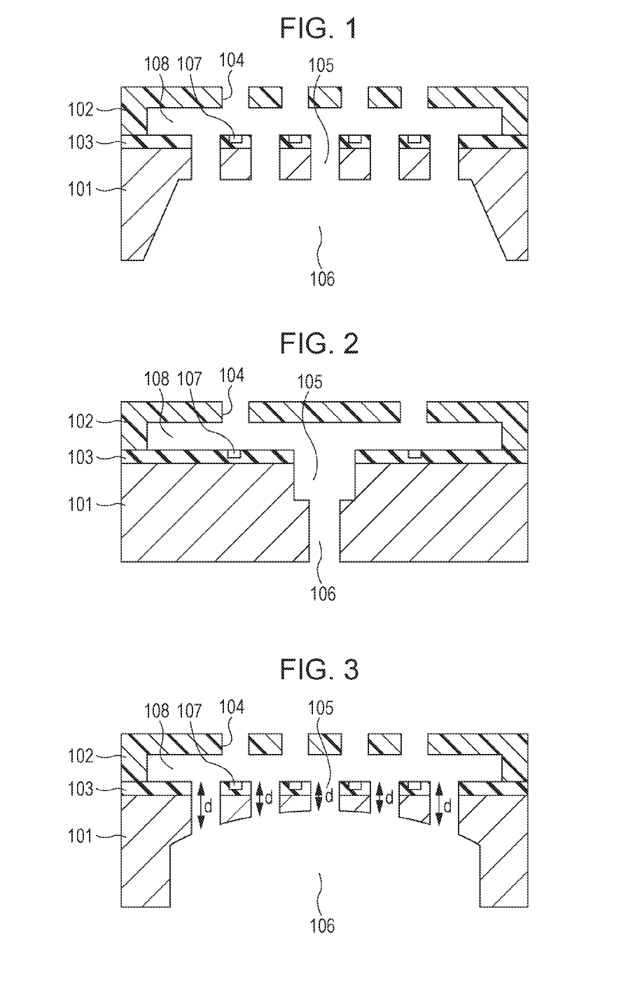

As mentioned in Japanese Patent Laid-Open No. 2004-237734, however, machining an ink supply path as in FIG. 1 through bidirectional processing of a silicon substrate, from its front and back sides, leads to the depth d of the first ink supply paths 105 being determined by the depth of the second ink supply path 106 as illustrated in FIG. 3. In particular, machining the second ink supply path 106 with the use of silicon dry etching generally gives the second ink supply path 106 a broad distribution of depths, therefore resulting in a broad distribution of depths of the first ink supply paths 105, because of greatly varied etching rates and a great machining depth.

A broad distribution of depths d of the first ink supply paths 105 leads to a broad distribution of flow resistances of the path, which causes variations in the speed of ink feeding to the nozzles and affects printing characteristics. Furthermore, too broad a distribution of depths of the second ink supply path 106 can cause part of the silicon substrate to burst. This sort of burst can cause the first ink supply paths 105 to be lost and the nearby circuits and wiring to break after etching.

The methods according to certain aspects of the disclosure for machining a silicon substrate can be applied to the production of micromachines such as acceleration sensors, as well as to methods for producing a substrate for a liquid ejection head.

To make an aspect of the disclosure clearly understood, the following describes a method for producing a liquid ejection head substrate as an embodiment of the subject disclosure.

### Embodiment 1

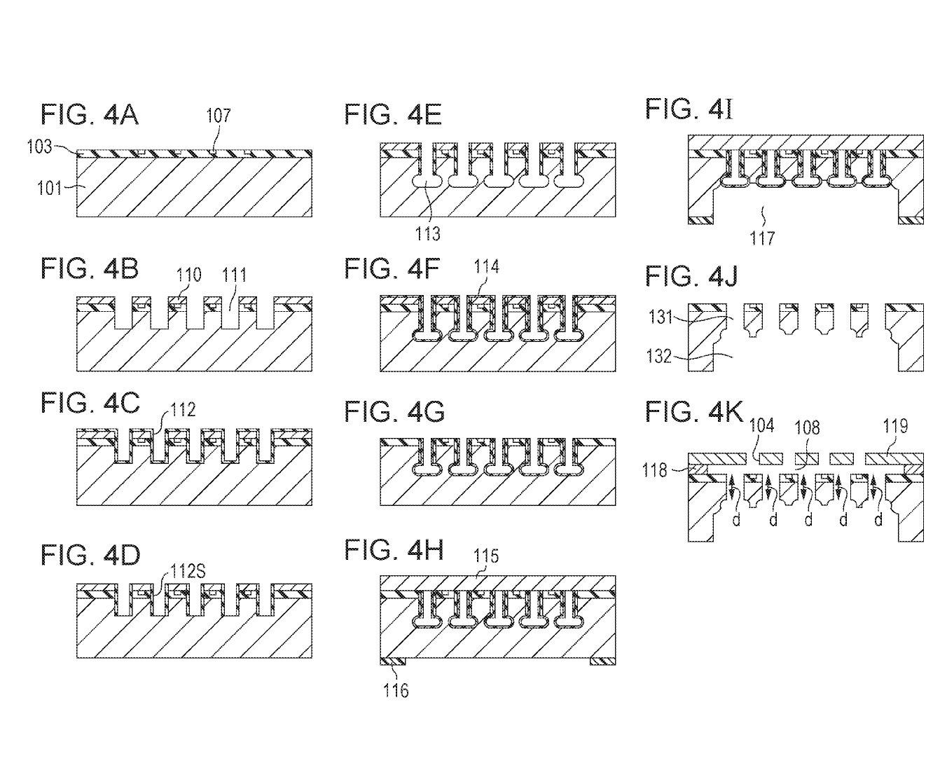

FIGS. 4A to 4K illustrate how a method according to an embodiment of the disclosure for machining a silicon substrate can be used to produce a substrate for a liquid ejection head.

First, as illustrated in FIG. 4A, a silicon substrate 101 is prepared that has energy generators 107, elements configured to generate energy to be used for liquid ejection. On the front surface (first surface) of the silicon substrate 101, there is a front membrane layer 103 including elements such as wiring and an interlayer insulating film.

A front etching mask 110 is formed on the front membrane layer 103 on the silicon substrate 101 using a photoresist or similar method, the front membrane layer 103 is etched, and the silicon substrate 101 is etched to create first recesses 111 (FIG. 4B). The front etching mask 110 covers elements in need of protection, such as the energy generators 107 and a circuit region. The first recesses 111 can be machined vertically, hence anisotropic dry etching can be used to etch the silicon substrate 101. Silicon is machined in the vertical direction of the substrate through a plasma discharge in a gas such as SF₆, Cl₂, C₄F₈, CF₄, CBrF₃, or similar. The “Bosch process” etching, which involves alternately repeating etching with a fluorine-containing gas, e.g., SF₆, and deposition of a fluorocarbon film on the side walls using C₄F₈ or similar gas, is an easy way of machining in the vertical direction of the substrate. The first recesses 111 can have any shape in plan view, examples including round shapes such as a perfect circle and an ellipse and polygonal shapes such as a rectangle and a hexagon. Creating the first recesses 111 symmetrically on both sides of the energy generators 107 will ensure stable liquid ejection through nozzles.

A sidewall-protecting film 112S is then formed on the side walls of the first recesses 111. As the precursor to the sidewall-protecting film 112S, a protective film 112 is first formed on the entire front surface of the substrate (FIG. 4C). Its thickness can be such that the sidewall-protecting film 112S fully withstands the undermentioned process of etching cavities.

An example of a way to form the protective film 112 is film formation in the etching chamber. For instance, a fluorocarbon film can be formed on the entire wafer through plasma deposition of a fluorocarbon gas such as C₄F₈.

The substrate is then etched using ions that travel very straight in the vertical direction of the substrate (e.g., ions of a fluorine-containing compound) so that the film is selectively removed except from the side walls. This produces a sidewall-protecting film 112S on the side walls of the first recesses 111, as illustrated in FIG. 4D.

To take another example, it is possible to form a silicon oxide film on the inner walls of the first recesses 111 through a discharge in an oxidative gas in the etching chamber and then etch the silicon oxide film using dry etching, a highly vertical etching technique, except on the side walls of the first recesses 111. The sidewall-protecting film 112S can also be a silicon nitride film formed through a discharge in a nitriding gas.

Examples of techniques that can be used to form the protective film 112 include sputtering, chemical vapor deposition (CVD), and atomic layer deposition (ALD). The material of which the protective film 112 is made can be one that exhibits high etching selectivity over silicon. Specific examples of the protective film 112 include a fluorocarbon film, a film of a metal selected from Ta, Ti, Ni, W, and Zr, a film of a nitride of any of these metals, a film of an oxide of any of these metals, and a film of a nitride or oxide of silicon or aluminum. Films of these materials can be likewise removed using plasma etching, except from the side walls.

After the formation of the sidewall-protecting film 112S, the silicon that appears in the bottom section of the first recesses 111 is etched. Both dry etching and wet etching can be used. The following description of this embodiment is based on the use of dry etching.

Dry etching is performed to etch the silicon substrate 101 in its vertical and horizontal directions (hereinafter the substrate vertical and horizontal directions, respectively). During this process of etching, the side walls of the first recesses 111 are protected by the sidewall-protecting film 112S, whereas the bottom section of the first recesses 111 is scraped to create cavities 113 (FIG. 4E). The cavities 113 have a larger spatial-cross-sectional-area section than the first recesses 111 in the substrate horizontal direction. In this embodiment, the etching of the cavities 113 is terminated before adjacent cavities communicate with each other.

This process of etching for the creation of the cavities 113 can be done through a form of plasma etching in which an ion-depleted and radical-rich plasma gas isotropically scrapes the silicon. The use of a plasma gas such as SF₆, Cl₂, C₄F₈, CF₄, and CBrF₃ with an adjusted substrate bias voltage or similar arrangement is a way to control ions from being brought toward the substrate.

The process of etching the cavities 113 can also be based on dry etching using XeF₂. Involving no plasma, this form of etching can advantageously be conducted with less plasma-related effects (e.g., the loading effect and damage).

After the formation of the cavities 113, an etching stopper film 114 is formed on the inner walls of the cavities 113 (FIG. 4F). The etching stopper film 114 can be made of a material that exhibits high etching selectivity over silicon. The function of the etching stopper film 114 is to stop etching in the undermentioned process of machining a second recess from the back surface (a second surface, located opposite the first surface) of the silicon substrate. The thickness of the etching stopper film 114 is therefore large enough that the etching of the second recess can be terminated.

The etching stopper film 114 may be formed through the aforementioned deposition of a fluorocarbon film in the etching chamber. The etching stopper film 114 can also be produced as a silicon oxide or silicon nitride film through the oxidation or nitridation of the inner walls of the cavities 113 in the etching chamber with the use of an agent such as oxygen or nitrogen plasma. It is also possible to form the etching stopper film 114 using any of the film deposition techniques listed in describing the formation of the protective film 112. In particular, ALD allows all of the inner walls of the cavities 113 to be covered. Examples of materials of which the etching stopper film 114 can be made are the same as those for the protective film 112.

Another possible example of the etching stopper film 114 is a resin film. In general, resin films exhibit high etching selectivity for gases used to etch silicon. Examples of polymers of which the resin film can be made include acrylic polymers, polyimides, silicone polymers, fluorinated polymers, epoxy polymers, and polyether amides. These polymers can be formed into film using, for example, spin coating, slit coating, or spray coating.

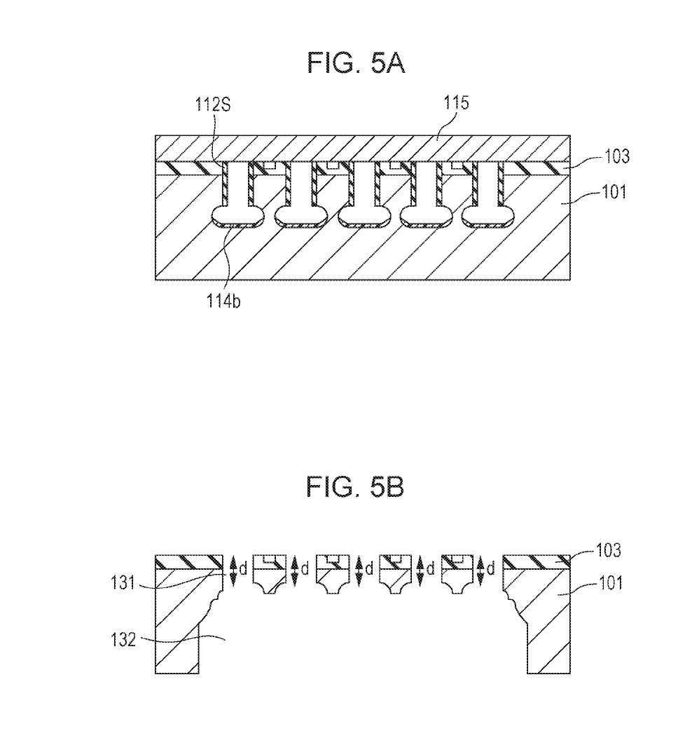

The etching stopper film 114 need not cover all of the inner walls of the cavities 113. The etching stopper film 114 covers at least the inner wall of the cavities 113 that extends in the substrate horizontal direction, and the only coverage requirement is that the etching stopper film 114 be able to mask the side walls of the first recesses 111 from being scraped during the undermentioned process of machining a second recess from the back surface of the silicon substrate. For example, the etching stopper film 114 may be structured like the etching stopper film 114b in FIG. 5A, which covers only the bottom surface of the cavities 113 and leaves the side walls of the first recesses 111 and the surface of the inner side walls of the cavities 113 exposed.

In order for the etching stopper film 114 to fully cover the surface of the inner wall of the cavities 113 that extends in the substrate horizontal direction, it is necessary that the cavities 113 be etched at least to a certain extent in the substrate horizontal direction. The extent of the etching of the cavities 113 in the substrate horizontal direction can be 5 μm or more. However, increasing the extent of the etching of the cavities 113 in the substrate horizontal direction too much leads to excessive etching in the substrate vertical direction, potentially causing the silicon layer lying between the first recesses 111 to be thin or the cavities 113 to reach the back surface of the substrate, since the etching of the cavities 113 proceeds in a substantially isotropic manner. Hence when the silicon substrate has a thickness of, for example, 750 μm, the total depth of etching can be 500 μm or less including the depth of the first recesses. This means that the cavities 113 can be created in such a manner that at least ⅓ of the thickness of the substrate is preserved. The cavities 113 may be created in such a manner that grinding of the substrate from its back surface for thinning, if it follows the formation of the cavities 113, leaves a layer of silicon that keeps the etching stopper film 114 unexposed.

The front etching mask 110 is then removed using solvent, ultrasonic cleaning, or similar. The etching stopper film 114 and the sidewall-protecting film 112S on the surface of the etching mask are lifted off together with the mask (FIG. 4G). A protector 115 is then attached to protect the front surface of the silicon substrate 101. The protector 115 can be, for example, a film such as a piece of UV- or thermal-release tape or a glass substrate having an adhesive coating.

A back etching mask 116 to be used in machining a second recess 117 is then formed on the side of the silicon substrate 101 where its back surface (second surface) is located (FIG. 4H). The back etching mask 116 can be, for example, a positive photoresist. After the formation of the back etching mask 116, the back side of the silicon substrate 101 is etched to create a second recess 117. Like the first recesses 111, the second recess 117 can be created through anisotropic dry etching. The cross-sectional area of the bottom surface of the second recess 117 is set to be greater than that of the bottom surface of the first recesses 111.

Etching the second recess 117 to the cavities 113 makes the etching stopper film 114 on the inner walls of the cavities 113 exposed (FIG. 4I). The etching stopper film 114 shields the surroundings of the first recesses 111 from plasma, protecting the surroundings of the first recesses 111.

Another advantage of this embodiment is easier endpoint detection, i.e., easier monitoring of the etching chamber for the endpoint of etching. Endpoint detection involves measuring light emitted by a silicon compound that forms when silicon is etched. The light emitted by the silicon compound fades in response to the decrease in the quantity of scrapable silicon that occurs when the silicon is sufficiently processed, indicating the endpoint of etching.

In the existing methods for silicon processing, the quantity of the silicon compound is the same before and after the time point when etching should be stopped because in these methods it is needed to terminate etching halfway in the silicon substrate. The above approach to endpoint detection is therefore infeasible in the existing methods. In this embodiment, however, at least part of the silicon etching is stopped by the etching stopper film 114 at the time point illustrated in FIG. 4I, reducing the quantity of silicon etched in the etching chamber. The intensity of the light emitted by the silicon compound drops, and a measuring instrument provided for endpoint detection tells the operator the timing. This is a great advantage from the perspective of the controllability of machining processes.

The etching of the second recess 117 is terminated when reaching the etching stopper film 114 in every part of the substrate. Lastly, at least part of the etching stopper film 114 is removed through wet etching, dry etching, application of a stripping solution, dry ashing, or similar, making the first recesses 111 communicate with the second recess 117. This way of removal may also remove the back etching mask 116 and the sidewall-protecting film 112S.

Then the back etching mask 116, if remaining, is removed through the use of a resist-stripping solution or oxygen ashing to separate the protector 115 from the substrate. The first recesses 111 turn into first hole sections (first ink supply paths) 131, and the second recess 117 and the cavities 113 turn into a second hole section (second ink supply path) 132, completing a through-hole that extends through the substrate from its first surface to the second surface (an ink supply path extending from the first surface to the second surface) (FIG. 4J).

FIG. 5B illustrates what would occur if the etching stopper film 114 was not formed on the inner walls of the cavities 113 in etching the second recess 117 and making it communicate with the first recesses 111. With no etching stopper film on the inner walls of the cavities, the silicon existing near the cavities 113 and the first recesses 111 would be etched. The resulting variations in the depth of the first recesses 111 as in FIG. 5B would cause the first ink supply paths 131 not to be uniform in depth.

The advantages of this embodiment are maintained even if the second recess 117 is etched using wet etching instead of dry etching on which the foregoing description is based. A possible form of wet etching is orientation-dependent anisotropic wet etching, which provides an easy way of etching in the substrate horizontal direction. In FIG. 4I, the silicon substrate 101 may be etched through immersion in an etchant that is a strong alkaline solution such as TMAH (trimethylanilinium hydroxide) or KOH (potassium hydroxide). In such a case, the back etching mask 116 and the etching stopper film 114 are made of a material resistant to the etchant. Examples of such materials include Hitachi Chemical “HIMAL” (trade name) organic polymers, as well as silicon nitrides and silicon oxides. These materials can be formed into film using known film formation techniques, such as spin coating, slit coating, CVD, and ALD.

A nozzle-perforated component 102 is then formed on the silicon substrate 101 which has had a through-hole (an ink supply path) created therethrough. This embodiment illustrates a case where a film-shaped photosensitive resin is attached to the silicon substrate 101 to complete a liquid ejection head.

The wall section 118 of the nozzle-perforated component is first formed. A dry film resist composed of a film substrate and a photosensitive resin coating is attached to the silicon substrate 101. The resist is then patterned into the wall section 118 of the nozzle-perforated component through optical exposure and development. The space left after this process of patterning will be a flow channel 108. The top 119 of the nozzle-perforated component is then formed likewise. A dry film resist is attached and patterned through optical exposure and development to create nozzles 104 through the top 119, completing a liquid ejection head. In the resulting head, the first liquid supply paths 131 have equal depths d (FIG. 4K).

### Embodiment 2

In Embodiment 1, the nozzle-perforated component is produced through the attachment of films because there are deep and open depressions in the front surface of the silicon substrate restricting options. This embodiment illustrates a production process in which there are some options for the way to form the nozzle-perforated component besides film attachment.

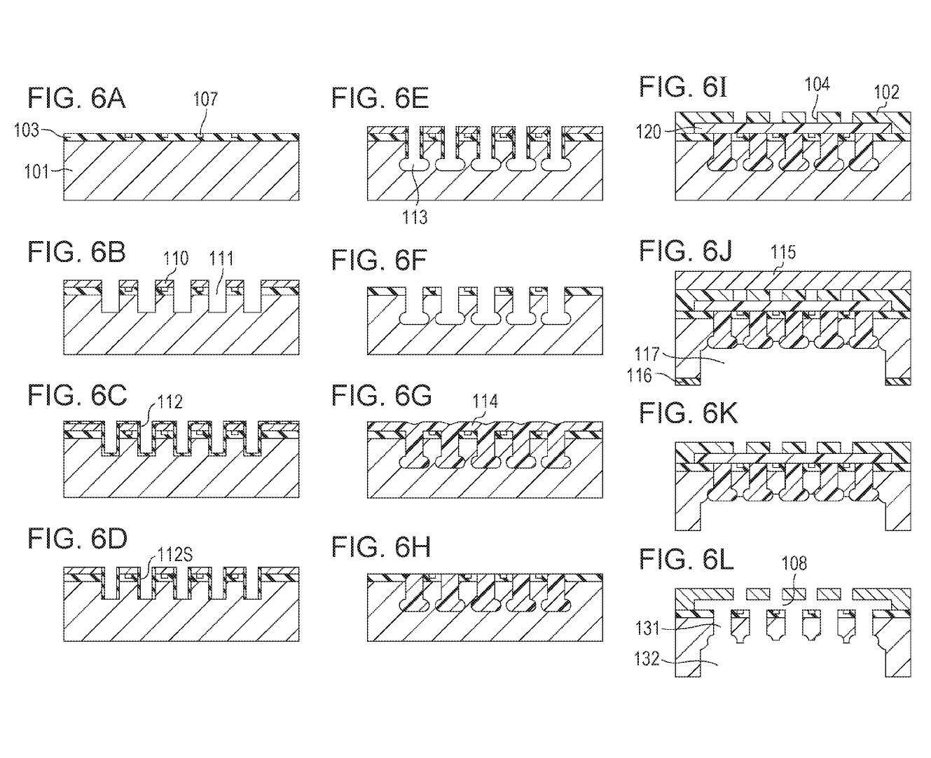

FIGS. 6A to 6L illustrate a method according to this embodiment for producing a substrate for a liquid ejection head. This method is the same as that in Embodiment 1 up until the creation of cavities 113 (FIGS. 6A to 6E).

The front etching mask 110 is then removed through, for example, the use of a resist-stripping solution, and the sidewall-protecting film 112S is removed through wet etching, dry etching, application of a stripping solution, asking, or similar (FIG. 6F). The depressions in the front surface of the silicon substrate 101 are then plugged up with an etching stopper film 114 (FIG. 6G). The depressions in the front surface of the silicon substrate 101 can be plugged up well with the etching stopper film 114 through, for example, the application of a resin material using spin coating or slit coating. Any commonly used fluidic resin material can be used, examples including acrylic polymers, polyimides, silicone polymers, fluorinated polymers, epoxy polymers, and polyether amides.

The use of a highly removable material for the etching stopper film 114 will help in removing the etching stopper film 114 filling and blocking the first recesses 111 and the cavities 113 after the machining of the second recess 117 from the back surface of the silicon substrate 101.

In particular, photosensitive polymers become highly removable and exhibit high removal selectivity when irradiated with light. Examples of photosensitive polymers include PMMA (polymethyl methacrylate), a class of acrylic materials, Kayaku MicroChem “SU-8” (trade name) epoxy polymer, and Tokyo Ohka Kogyo “ODUR” (trade name) polymethyl isopropenyl ketone.

After the implantation of the etching stopper film 114, the front surface of the substrate may optionally be smoothened through, for example, CMP (chemical mechanical polishing). This process of smoothing may include removing the excess of the etching stopper film 114, the part of the film lying on the substrate (FIG. 6H).

Plugging up the depressions in the front surface of the silicon substrate 101 with the etching stopper film 114 to make the surface smooth advantageously provides greater freedom of choice in making the nozzle-perforated component. To be more specific, this allows the use of various techniques to form the nozzle-perforated component including film formation techniques based on vapor phase epitaxy, such as sputtering, CVD, and vacuum evaporation, and coating techniques, such as spin coating and slit coating.

A flow channel mold 120, which is a film occupying the space that will serve as a liquid passage in the finished head, is formed on the smoothened silicon substrate 101 and made into a channel pattern. A film as the precursor to the nozzle-perforated component 102 is then formed and patterned with nozzles 104 (FIG. 6I). Examples of film formation techniques that can be used to form these films include vapor phase epitaxy, such as sputtering, CVD, and vacuum evaporation, and coating techniques, such as spin coating and slit coating. These films can be made of, for example, inorganic materials or organic polymers.

The flow channel mold 120 and the precursor to the nozzle-perforated component 102 may be patterned using dry etching through an etching mask. Alternatively, the flow channel mold 120 and the precursor to the nozzle-perforated component 102 may be made of photosensitive polymers so that they can be patterned through optical exposure and development. For example, the flow channel mold 120 and the precursor to the nozzle-perforated component 102 can be made of positive and negative photosensitive polymers, respectively.

A protector 115 is attached to the top of the nozzle-perforated component 102, and then the back side is processed. First, a second recess 117 is etched with a back etching mask 116 on the back side of the silicon substrate 101 until the etching stopper film 114 is exposed (FIG. 6J).

The back etching mask 116 is then removed, and the protector 115 is separated from the substrate (FIG. 6K). Lastly, the flow channel mold 120 and the etching stopper film 114 are removed, completing a liquid ejection head (FIG. 6L). These removal processes can be done through immersion in a chemical solution such as a stripping solution. For example, when the flow channel mold 120 and the etching stopper film 114 are positive photosensitive resin materials, ultraviolet radiation is directed to the front side of the silicon substrate 101. If the nozzle-perforated component 102, located on the front side, is ultraviolet impermeable, ultraviolet radiation is directed to the back side of the silicon substrate 101. This process of ultraviolet irradiation and exposure makes the polymers highly soluble in the stripping solution. Subsequent sonication in an alkali developer as the stripping solution dissolves away the flow channel mold 120 and the etching stopper film 114. The etching stopper film 114 may also be removed using any other technique, such as dry etching or dry asking. The method for the removal of the flow channel mold 120 and that for the etching stopper film 114 may be different.

### Embodiment 3

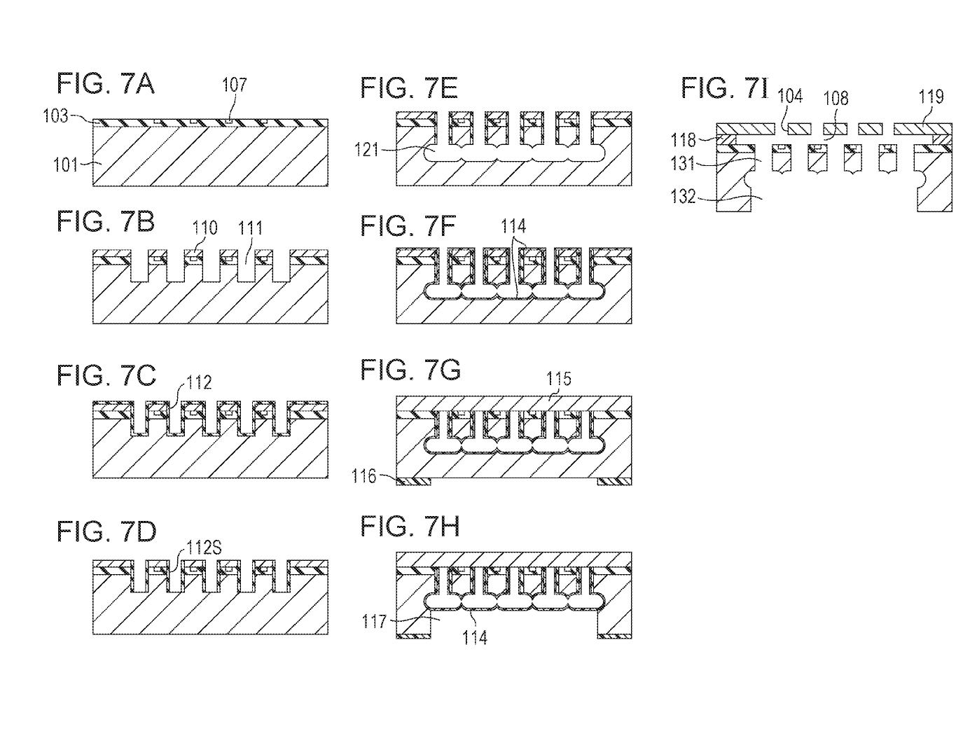

Embodiment 3 is a production method that offers improved accuracy in the depth not only of the first recesses, but also of the second recess. FIGS. 7A to 7I illustrate a method according to this embodiment for producing a substrate for a liquid ejection head. This method is the same as that in Embodiment 1 up until before the creation of cavities 113 (FIGS. 7A to 7D).

The cavities 113 are etched to an extent that adjacent cavities communicate with each other. After the completion of etching, a hollow channel 121 that communicates with all of predetermined first recesses 111 is left in the silicon substrate 101 as illustrated in FIG. 7E.

An etching stopper film 114 is then formed in such a manner that it extends at least on the bottom surface of the hollow channel 121, i.e., the surface of the hollow channel 121 closer to the back surface of the silicon substrate (FIG. 7F). Examples of processes through which this film can be produced are the same as those described in Embodiment 1. For instance, the etching stopper film 114 may be formed through the deposition of a fluorocarbon film in the etching chamber. The etching stopper film 114 can also be produced as a silicon oxide or silicon nitride film through the oxidation or nitridation of the inner walls of the hollow channel 121 in the etching chamber with the use of an agent such as oxygen or nitrogen plasma. It is also possible to form the etching stopper film 114 in a separate film formation system that performs, for example, sputtering, CVD, or ALD. In particular, ALD allows all of the inner walls of the hollow channel 121 to be covered. Furthermore, etching the stopper film 114 may be formed through the application of a resin material using spin coating, slit coating, or spray coating. The etching stopper film 114 can also be formed to plug up the hollow channel 121 and the first recesses 111 as in Embodiment 2.

The front etching mask 110 is then removed, and a protector 115 is attached to the top of the silicon substrate 101. After that, a back etching mask 116 to be used in machining a second recess 117 is formed on the back side of the silicon substrate 101 (FIG. 7G). The hollow channel 121, the etching stopper film 114, and the second recess 117 are so designed that the etching stopper film 114 on the inner walls of the hollow channel 121 will completely stop the second recess 117 from being etched through contact with the entire bottom surface of the second recess 117.

The process of etching the second recess 117 is fully terminated by the etching stopper film 114 when the second recess 117 has reached the etching stopper film 114 (FIG. 7H). As a result, the depth of the second recess 117 (second hole section 132) and that of the first recesses 111 (first hole sections 131) are precisely controlled.

Removing the etching stopper film 114 after the end of etching completes the machining of a through-hole in the silicon substrate. A nozzle-perforated component including a wall section 118 and a top 119 perforated with nozzles 104 is then formed on the front side of the silicon substrate in the same way as in Embodiment 1, completing a liquid ejection head in which a second hole section (second liquid supply path) 132, first hole sections (first liquid supply paths) 131, a flow channel 108, and nozzles 104 communicate with one another (FIG. 7I). It is also possible to form the etching stopper film 114 in the same way as in Embodiment 2 and machine the second recess 117 after the formation of the nozzle-perforated component 102.

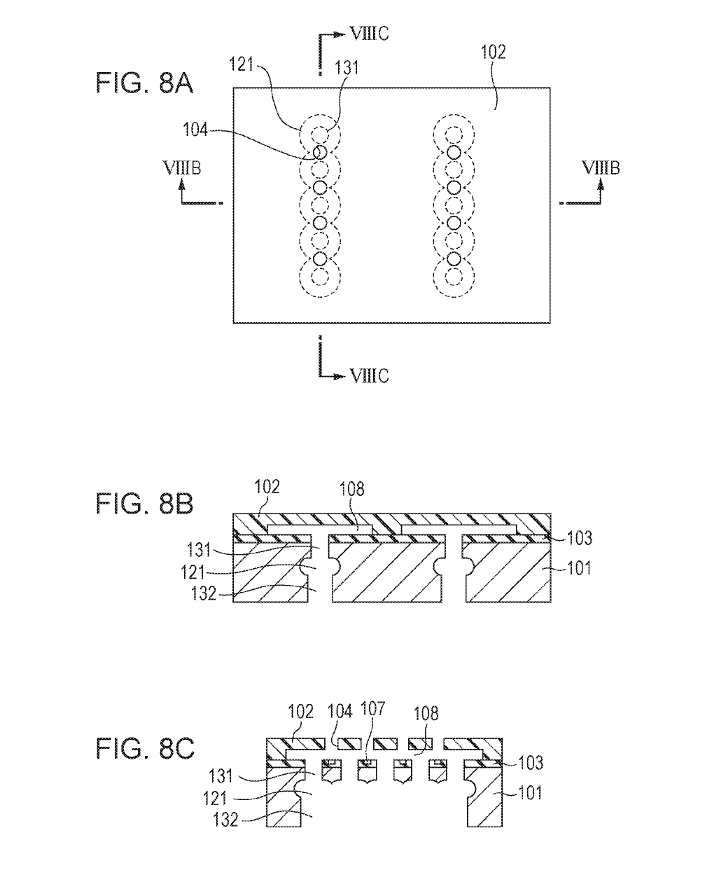

FIGS. 8A, 8B, and 8C are a plan view, a cross-sectional view along line VIIIB-VIIIB, and a cross-sectional view along line VIIIC-VIIIC, respectively, of a liquid ejection head that can be produced in accordance with this embodiment. As illustrated in FIG. 8A, the top surface of the liquid ejection head is the surface of a nozzle-perforated component 102 perforated with two lines of nozzles 104. As can be seen from FIG. 8B, there are two through-holes which are independent of, or out of communication with, each other in the direction transverse to the lines of the nozzles 104. As for a cross-section along the lines of the nozzles 104, energy generators 107 and first liquid supply paths 131 alternate under the nozzles 104 as in FIG. 8C. The first liquid supply paths 131 are plural independent micropores facing the front side of the substrate, and there are also second liquid supply paths 132 created from the back side of the substrate like trenches extending along the lines of the first liquid supply paths 131. Hollow channels 121 created in the substrate allow the second liquid supply paths 132 to communicate with the first liquid supply paths 131.

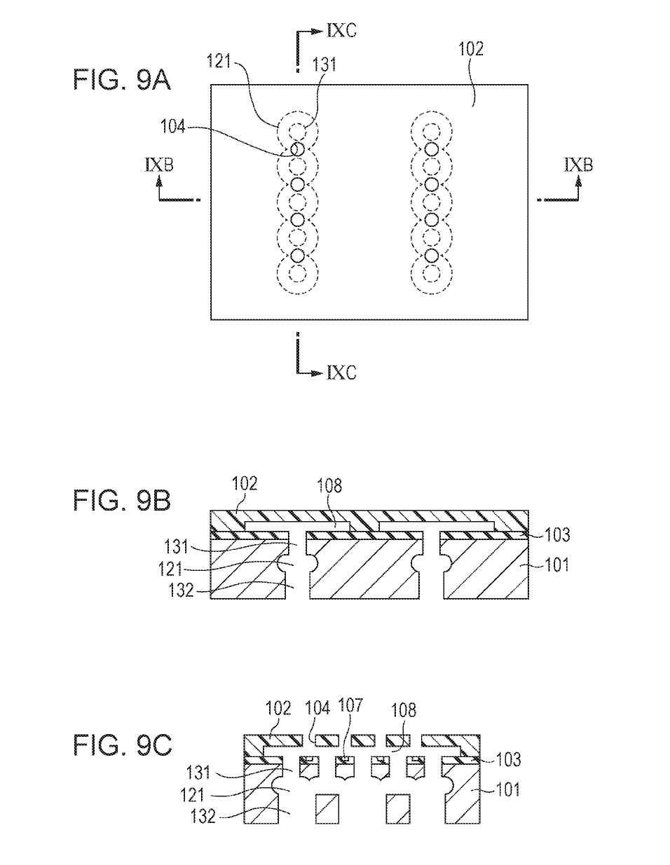

The hollow channels 121 extend along the lines of the first liquid supply paths 131, and the width of the hollow channels 121 is larger than that of the first liquid supply paths 131 and the second liquid supply paths 132. The second liquid supply paths 132 may be segmented trenches instead of being continuous trenches as in FIGS. 8A to 8C. For example, the second liquid supply paths 132 may be machined in plural segments as in the liquid ejection head illustrated in FIGS. 9A to 9C.

In this embodiment, the spatial-cross-sectional-area section of a second liquid supply path 132 in the substrate horizontal direction is smaller than that of a hollow channel 121, and the resulting small volume of the second liquid supply path 132 limits the freedom of design for a through-hole. A second recess in this embodiment can, however, be machined in two or more levels to increase the volume of a second liquid supply path.

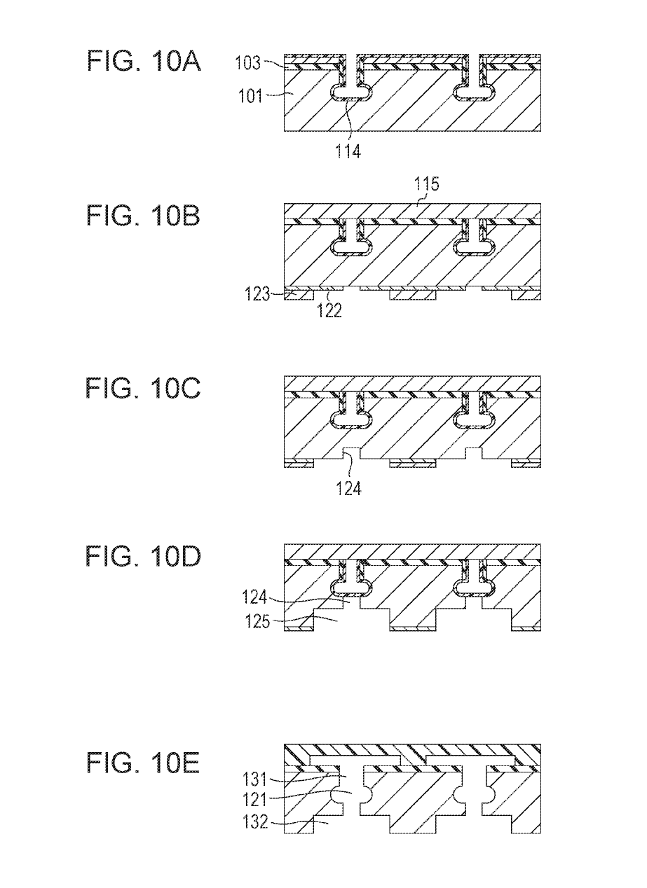

FIGS. 10A to 10E, cross-sectional process diagrams illustrating a method for producing a liquid ejection head which involves machining second recesses in two levels, provide an example of such a production method. The cross-sectional views are in the same direction as in FIG. 8B, i.e., the direction transverse to nozzles 104. This method is as illustrated in FIGS. 7A to 7F up until the formation of an etching stopper film 114. FIG. 10A is a cross-sectional diagram illustrating a state where an etching stopper film 114 has just been formed. The front etching mask 110 is then removed, and a protector 115 is attached for protection. A first etching mask 122 and a second etching mask 123 are then formed in this order on the back surface of the silicon substrate 101 (FIG. 10B), resulting in a two-level etching mask being produced on the back surface of the silicon substrate 101. This two-level etching mask is used for the machining of second recesses. The individual etching masks can be produced in the same way as in Embodiment 1.

Second recesses are then machined in an etching chamber. The first level 124 of the second recesses is first created using the first etching mask 122. The first etching mask 122 is exhausted when the etching has reached a predetermined depth (FIG. 10C). The second level 125 of the second recesses is then created using the remaining etching mask.

The first level 124 of the second recesses (the recesses that are created first) is designed small in terms of area so that its entire bottom surface comes into contact with the etching stopper film 114 under the hollow channels 121, and the second level of the second recesses (the recesses that are created second) is designed sufficiently large.

As a result, the second recesses are produced in two levels as illustrated in FIG. 10D. The etching of the first level, the level deeper than the second, is fully terminated by the etching stopper film 114, ensuring that the first liquid supply paths 131 and the second liquid supply paths 132 are uniform in depth. The operator can create the second level 125 of the second recesses to the desired depth after the termination of the etching of the first level 124.

Lastly, the etching stopper film 114 is removed, and a nozzle-perforated component 102 is formed on the front surface of the silicon substrate 101 to complete a liquid ejection head (FIG. 10E).

### Embodiment 4

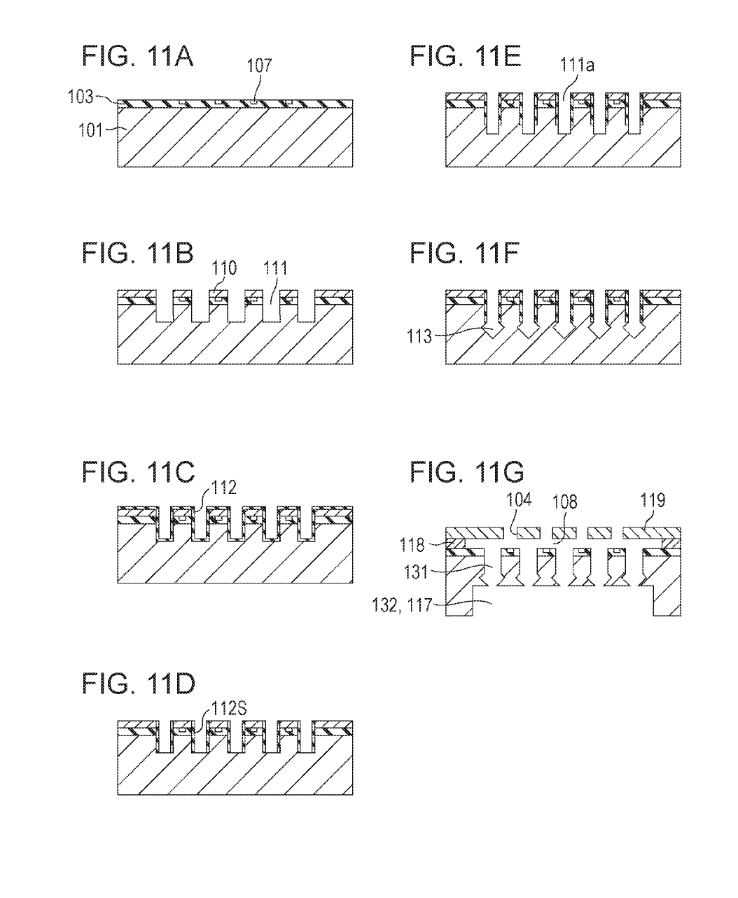

Embodiment 4 is a production method that allows reliable control of the extent of the etching of cavities in the substrate horizontal direction in Embodiments 1 to 3. FIGS. 11A to 11G are cross-sectional process diagrams illustrating a method according to this embodiment for producing a silicon substrate for a liquid ejection head. A front etching mask 110 is formed on the front surface of a silicon substrate 101, and first recesses 111 are machined vertically (FIG. 11B). A protective film 112 is then formed (FIG. 11C) and removed except from the side walls of the first recesses 111, leaving a sidewall-protecting film 112S (FIG. 11D).

The first recesses 111 are then vertically extended to the desired depth using dry etching (FIG. 11E; the extended first recesses numbered 111a), and there follows anisotropic wet etching from the front surface. A {100} silicon substrate is usually used for the silicon substrate 101 because the performance of the transistor formed on its front surface needs to be maintained. When such a silicon substrate is machined using anisotropic wet etching, {111} silicon surfaces are hardly etched because of very slow rates of etching on these surfaces. As a result, etching automatically terminates leaving polygonal cavities 113 defined by exposed {111} silicon surfaces as illustrated in FIG. 11F, and this can be used to control the extent of the etching of the cavities 113 in the substrate horizontal direction precisely. Examples of etchants for this process of anisotropic wet etching include strong alkali solutions, such as TMAH and KOH.

The sidewall-protecting film 112S illustrated in FIG. 11D and the front etching mask 110 may be resistant to anisotropic wet etching. Examples of materials of which they can be made include resin materials (e.g., Hitachi Chemical “HIMAL” (trade name)), as well as silicon nitrides and silicon oxides. These materials can be made into film through, for example, spin coating, slit coating, CVD, and ALD.

The shape of the cavities 113 created through anisotropic wet etching is controlled by the depth, and cross-sectional shape of the first recesses 111a illustrated in FIG. 11E, which are vertically created through anisotropic etching, and by the depth for which the first recesses 111a are protected by the sidewall-protecting film 112S. To increase the extent of the etching of the cavities 113 in the substrate horizontal direction (i.e., to make the spatial-cross-sectional-area section of the cavities 113 in the substrate horizontal direction larger), the operator can either extend the unprotected sidewall section of the first recesses 111a, the area not covered with the sidewall-protecting film 112S, by performing dry etching to a greater depth in the process illustrated in FIG. 11E or increase the open area of the first recesses 111.

After the completion of the creation of the cavities 113, the silicon substrate and the wall section 118 and the top 119 of the nozzle-perforated component are machined in the same way as in Embodiment 1, completing a liquid ejection head (FIG. 11G).

### EXAMPLES

The following describes some examples of liquid ejection heads produced in accordance with a method described in Embodiment 1. These examples should not be construed as limiting any aspect of the subject disclosure.

An 8-inch silicon substrate 101 (a thickness of 730 μm) was subjected to a photolithographic process, in which aluminum wiring, a silicon oxide interlayer insulating film (a front membrane layer 103), a tantalum nitride heater electrode pattern 107, and a contact pad for electrical communication with an external control unit were formed on the top of the substrate (FIG. 4A).

The resulting structure was then coated with a positive resist for the formation of first recesses to a thickness of 10 μm through spin coating. The coating was optically exposed using an ultraviolet projection exposure system and developed with an alkali solution, yielding a perforated front etching mask 110 for the machining of plural small recesses. The shape of the holes was 40×40 μm², and the hole pitch was 200 μm.

The silicon oxide interlayer insulating film was vertically machined at the openings of the resist mask using an oxide-film dry etching chamber with CF₄ gas plasma, until the silicon under the oxide appeared on the surface.

Then the Bosch process, i.e., repeated etching with a SF₆ gas and deposition of a film using a fluorocarbon gas, was performed using a silicon dry etching chamber designed for it, vertically machining silicon to form first recesses 111 with a depth of 100 μm (FIG. 4B).

Then ALD was carried out to form a 0.2-μm thick Al₂O₃ film 112 over the entire front surface of the substrate (FIG. 4C). Vertical Ar ion etching was then conducted to remove the Al₂O₃ film except from the side walls of the first recesses 111, leaving a sidewall-protecting film 112S (FIG. 4D).

The silicon dry etching chamber was then used once again to isotropically etch the silicon exposed on the bottom surface of the first recesses with a SF₆ gas, creating cavities 113 (FIG. 4E). The extent of silicon etched in the substrate horizontal direction (extent of side etching) was 20 μm.

A 0.2-μm thick Al₂O₃ film as the etching stopper film 114 was then formed on the inner walls of the cavities using an ALD system (FIG. 4F). After that, the front etching mask 110 was lifted off through ultrasonic cleaning in a resist-stripping solution, together with the Al₂O₃ films on it (112 and 114) (FIG. 4G).

The front surface of the substrate was then protected through lamination with UV-release tape as the protector 115 using a vacuum laminator, and the back surface of the silicon substrate was ground using a grinder until the thickness of the substrate was 500 μm.

A positive resist was then applied to the ground surface and developed into a back etching mask 116 for the machining of a second recess (FIG. 4H).

A second recess 117 was then machined from the back side to a width of 500 μm and a depth of roughly 300 to 400 μm using the silicon dry etching chamber, until the Al₂O₃ film formed on the inner walls of the cavities as the etching stopper film 114 became exposed in the bottom section of the second recess 117 (FIG. 4I).

The Al₂O₃ film as the etching stopper film 114 was then removed through etching with Ar ions from the back side, and the back etching mask 116 was removed using a resist-stripping device. Lastly, the UV-release tape on the front side was removed through ultraviolet irradiation, completing the creation of a through-hole in the silicon substrate (FIG. 4J).

A 20-μm thick negative dry film resist (Tokyo Ohka Kogyo “TMMF” (trade name)) was then attached to the front surface of the silicon substrate. The attached resist was patterned into a wall section 118 of a nozzle-perforated component through optical exposure using an exposure system followed by development. The wall section 118 of the nozzle-perforated component was then laminated with another piece of the same dry film resist, and this resist was optically exposed and developed into a nozzle-perforated top 119 of the nozzle-perforated component.

The resulting structure was then oven-baked at 200° C. for 1 hour, completing a liquid ejection head illustrated in FIG. 4K.

The first liquid supply paths 131 had substantially equal depths d around 100 μm.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2014-256865, filed Dec. 19, 2014, which is hereby incorporated by reference herein in its entirety.

What is claimed is:

1. A method for machining a silicon substrate by creating a hole section through the silicon substrate from a first surface to an opposite second surface of the substrate, the method comprising:
(A) machining a first recess in the first surface of the silicon substrate;
(B) forming a sidewall-protecting film on a side wall of the first recess;
(C) etching a bottom section of the first recess to create a cavity, the cavity having a larger spatial-cross-sectional-area section than the first recess in a horizontal direction of the substrate;
(D) forming an etching stopper film on at least an inner wall of the cavity extending in the horizontal direction of the substrate;
(E) machining a second recess from the second surface of the silicon substrate;
(F) making the etching stopper film exposed in at least part of the second recess; and
(G) removing at least part of the exposed etching stopper film to make the first recess communicate with the second recess.

2. The method according to claim 1 for machining a silicon substrate, wherein:
the first recess includes a plurality of recesses; and
in (C), the etching makes adjacent cavities communicate with each other; in (D), the etching stopper film is formed to extend across the communicating cavities; and in (E) and (F), the second recess is created to make the etching stopper film on the inner wall of the cavities exposed for at least two adjacent cavities.

3. The method according to claim 2 for machining a silicon substrate, wherein in (E), the second recess is created in at least two levels.

4. The method according to claim 1 for machining a silicon substrate, wherein in (C), the etching includes orientation-dependent anisotropic wet etching.

5. The method according to claim 1 for machining a silicon substrate, wherein in (D), the etching stopper film is formed using atomic layer deposition.

6. The method according to claim 1 for machining a silicon substrate, wherein in (D), the etching stopper film includes a fluorocarbon film, a film of a metal selected from Ta, Ti, Ni, W, and Zr, a film of a nitride of the metal, a film of an oxide of the metal, or a film of a nitride or oxide of silicon or aluminum.

7. The method according to claim 1 for machining a silicon substrate, wherein in (D), the etching stopper film is a resin film.

8. The method according to claim 7 for machining a silicon substrate, wherein the resin film is a film of a photosensitive polymer.

9. The method according to claim 1 for machining a silicon substrate, wherein in (E), the second recess is created using dry etching.

10. A liquid ejection head comprising:
a plurality of first liquid supply paths facing a first surface of a silicon substrate;
a hollow channel under the plurality of first liquid supply paths in the silicon substrate, the hollow channel having a larger spatial cross-sectional-area section than the first liquid supply paths in a horizontal direction of the substrate; and
a second liquid supply path under the hollow channel, the second liquid supply path having a smaller spatial-cross-sectional-area section than the hollow channel in the horizontal direction of the substrate and facing a second surface of the silicon substrate,
the first liquid supply paths communicating with the hollow channel, and
the hollow channel communicating with the second liquid supply path.
